(19) United States
(12) Patent Application Publication
(10) Pub. No.: US 2024/0414915 A1
(43) Pub. Date: Dec. 12, 2024

(54) THREE-DIMENSIONAL SEMICONDUCTOR MEMORY DEVICE AND ELECTRONIC SYSTEM INCLUDING THE SAME

(71) Applicant: SAMSUNG ELECTRONICS CO., LTD., Suwon-si (KR)

(72) Inventors: Hyunuk Jeon, Suwon-si (KR); Dong Young Kim, Suwon-si (KR); Byeongheon Min, Suwon-si (KR)

(21) Appl. No.: 18/403,487

(22) Filed: Jan. 3, 2024

(30) Foreign Application Priority Data
Jun. 12, 2023 (KR) 10-2023-0074704

(51) Int. Cl. H10B 43/27; H10B 43/40

(52) U.S. Cl. CPC H10B 43/27; H10B 43/40

(57) ABSTRACT

Disclosed are three-dimensional semiconductor memory devices and electronic systems. The three-dimensional semiconductor memory device comprises stack structures that include interlayer dielectric layers and gate electrodes that are alternately stacked on a substrate, vertical channel structures that penetrate the stack structures, and a separation structure that runs in a first direction across between the stack structures. The separation structure includes a first portion that extends in a vertical direction from the substrate, and a second portion on the first portion and including a material different from a material of the first portion. A top surface of the second portion is at a level the same as that of top surfaces of the vertical channel structures.

### CROSS-REFERENCE TO RELATED APPLICATION

This U.S. nonprovisional application claims priority under 35 U.S.C § 119 to Korean Patent Application No. 10-2023-0074704 filed on Jun. 12, 2023 in the Korean Intellectual Property Office, the disclosure of which is hereby incorporated by reference in its entirety.

### TECHNICAL FIELD

The present disclosure relates to a three-dimensional semiconductor memory device, and more particularly, to a nonvolatile three-dimensional semiconductor memory device including a vertical channel structure, a method of fabricating the same, and an electronic system for achieving the same.

### BACKGROUND

Semiconductor devices capable of storing a large amount of data in an electronic system that requires data storage are in demand. Semiconductor devices have been highly integrated to meet high performance and low manufacturing cost standards. Integration of typical two-dimensional or planar semiconductor devices is primarily determined by the area occupied by a unit memory cell, such that integration is greatly influenced by the available technology for forming fine patterns. However, the processing equipment for fine patterns is expensive and limits the integration of the two-dimensional or planar semiconductor devices. Therefore, there have been proposed three-dimensional semiconductor memory devices having three-dimensionally arranged memory cells.

### SUMMARY

The present disclosure provides a three-dimensional semiconductor memory device with improved electrical properties and increased reliability.

The present disclosure provides an electronic system including a three-dimensional semiconductor memory device with improved electrical properties and increased reliability.

The object of the present disclosure is not limited to the mentioned above, and other objects which have not been mentioned above will be clearly understood to those skilled in the art from the following description.

In general, aspects of the subject matter described in this specification can be embodied in a three-dimensional semiconductor memory device including: a plurality of stack structures that include a plurality of interlayer dielectric layers and a plurality of gate electrodes that are alternately stacked on a substrate; a plurality of vertical channel structures that penetrate the stack structures; and a separation structure that runs in a first direction across between the stack structures. The separation structure may include: a first portion that extends in a vertical direction from the substrate; and a second portion on the first portion, the second portion including a material different from a material of the first portion. A top surface of the second portion of the separation structure may be at a level the same as a level of top surfaces of the vertical channel structures.

Another general aspect can be embodied in a three-dimensional semiconductor memory device including: a substrate that includes a cell array region and a contact region adjacent in a first direction to the cell array region; a peripheral circuit structure on the substrate, the peripheral circuit structure including a plurality of peripheral circuit transistors; a source structure on the peripheral circuit structure; a plurality of stack structures that include a plurality of interlayer dielectric layers and a plurality of gate electrodes that are alternately stacked on the source structure; a plurality of vertical channel structures that penetrate the stack structures and are connected to the source structure; a separation structure that runs in the first direction across between the stack structures; a selection mold structure on the stack structures, the selection mold structure including a selection semiconductor layer; an upper separation structure that penetrates the selection mold structure and contacts the separation structure; a plurality of upper vertical channel structures that penetrate the selection mold structure and are correspondingly connected to the vertical channel structures; and a separation dielectric pattern in the selection mold structure, the separation dielectric pattern penetrating the selection semiconductor layer. The separation structure may include: a first portion on a second substrate; and a second portion between the first portion and the selection mold structure. A top surface of the second portion may be at a level the same as a level of top surfaces of the vertical channel structures.

Another general aspect can be embodied in an electronic system including: a three-dimensional semiconductor memory device that includes a substrate, a plurality of stack structures including a plurality of interlayer dielectric layers and a plurality of gate electrodes that are alternately stacked on the substrate, a plurality of vertical channel structures that penetrate the stack structures, a separation structure between the stack structures, and an input/output pad on the stack structures; and a controller that has electrical connection through the input/output pad with the three-dimensional semiconductor memory device and controls the three-dimensional semiconductor memory device. The separation structure may include: a first portion that extends in a vertical direction from the substrate; and a second portion on the first portion, the second portion including a material different from a material of the first portion. A top surface of the separation structure may be at a level the same as a level of top surfaces of the stack structures.

### BRIEF DESCRIPTION OF DRAWINGS

FIG. 1 illustrates a simplified schematic diagram showing an example of an electronic system including a three-dimensional semiconductor memory device.

FIG. 2 illustrates a simplified perspective view showing an example of an electronic system including a three-dimensional semiconductor memory device.

FIGS. 3 and 4 illustrate cross-sectional views respectively taken along lines I-I′ and II-II′ of FIG. 2, showing a three-dimensional semiconductor memory device.

FIG. 5 illustrates a plan view showing an example of an a three-dimensional semiconductor memory device.

FIGS. 6 and 7 illustrate cross-sectional views respectively taken along lines I-I′ and II-II′ of FIG. 5, showing a three-dimensional semiconductor memory device.

FIGS. 8A to 8C illustrate enlarged cross-sectional views of section A depicted in FIG. 6, partially showing a three-dimensional semiconductor memory device.

FIG. 9 illustrates an enlarged cross-sectional view of section B depicted in FIG. 6, partially showing a three-dimensional semiconductor memory device.

FIGS. 10A to 13C illustrate plan and cross-sectional views showing a an example of an method of fabricating a three-dimensional semiconductor memory device.

FIGS. 10A, 11A, 12A, and 13A illustrate plan views showing an example of a three-dimensional semiconductor memory device.

FIG. 10B illustrates a cross-sectional view taken along line I-I′ of FIG. 10A.

FIG. 11B illustrates a cross-sectional view taken along line I-I′ of FIG. 11A.

FIGS. 12B, 12C, and 12D illustrate cross-sectional views taken along line I-I′ of FIG. 12A.

FIGS. 13B and 13C illustrate cross-sectional views taken along line I-I′ of FIG. 13A.

### DETAILED DESCRIPTION

In the following, like reference numerals may indicate like components throughout the description.

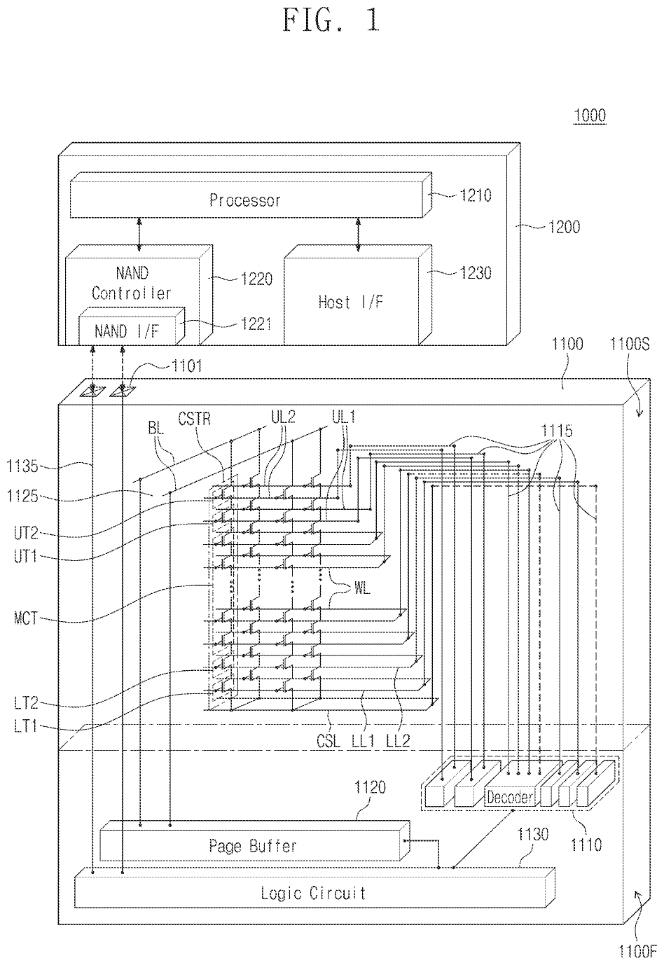

FIG. 1 illustrates a simplified schematic diagram showing an example of an electronic system including a three-dimensional semiconductor memory device.

Referring to FIG. 1, an electronic system 1000 includes a semiconductor device 1100 and a controller 1200 electrically connected to the semiconductor device 1100. The electronic system 1000 may be a storage device that includes a single or a plurality of semiconductor devices 1100 or may be an electronic device that includes the storage device. For example, the electronic system 1000 may be a solid-state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND Flash memory device. The semiconductor device 1100 may include a first structure 1100F and a second structure 1100S on the first structure 1100F. Alternatively, the first structure 1100F may be disposed on a side of the second structure 1100S.

The first structure 1100F may be a peripheral circuit structure that includes a decoder circuit 1110, a page buffer 1120, and a logic circuit 1130. The second structure 1100S may be a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. Although FIG. 1 depicts two of each the lower transistors LT1 and LT2 and the upper transistors UT1 and UT2, the number of each the lower transistors LT1 and LT2 and the upper transistors UT1 and UT2 can vary.

The upper transistors UT1 and UT2 may include string selection transistors, and the lower transistors LT1 and LT2 may include ground selection transistors. The first and second gate lower lines LL1 and LL2 may be gate electrodes of the lower transistors LT1 and LT2, respectively. The word lines WL may be gate electrodes of the memory cell transistors MCT, and the first and second gate upper lines UL1 and UL2 may be gate electrodes of the upper transistors UT1 and UT2, respectively.

For example, the lower transistors LT1 and LT2 may include a lower erase control transistor and a ground selection transistor that are connected in series. The upper transistors UT1 and UT2 may include a string selection transistor and an upper erase control transistor that are connected in series. One or both of the lower and upper erase control transistors may be employed to perform an erase operation in which a gate induced drain leakage (GIDL) phenomenon is used to erase data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F to the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

Although not shown, the first structure 1100F may include a voltage generator. The voltage generator may produce program voltages, read voltages, pass voltages, and verification voltages that are required for operating the memory cell strings CSTR. The program voltage may be relatively higher (e.g., about 20 V to about 40 V) than the read voltage, the pass voltage, and the verification voltage.

For example, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as program voltages applied to the word lines WL in a program operation. The page buffer 1120 may also include high-voltage transistors capable of withstanding high voltages.

The controller 1200 may include a processor 1210, a NAND controller 1220, and a host interface 1230. For example, the electronic system 1000 may include a plurality of semiconductor devices 1100, and in this case, the controller 1200 may control the plurality of semiconductor devices 1100.

The processor 1210 may control an overall operation of the electronic system 1000 that includes the controller 1200. The processor 1210 may operate based on predetermined firmware and may control the NAND controller 1220 to access the semiconductor device 1100. The NAND controller 1220 may include a NAND interface 1221 that processes communication with the semiconductor device 1100. The NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

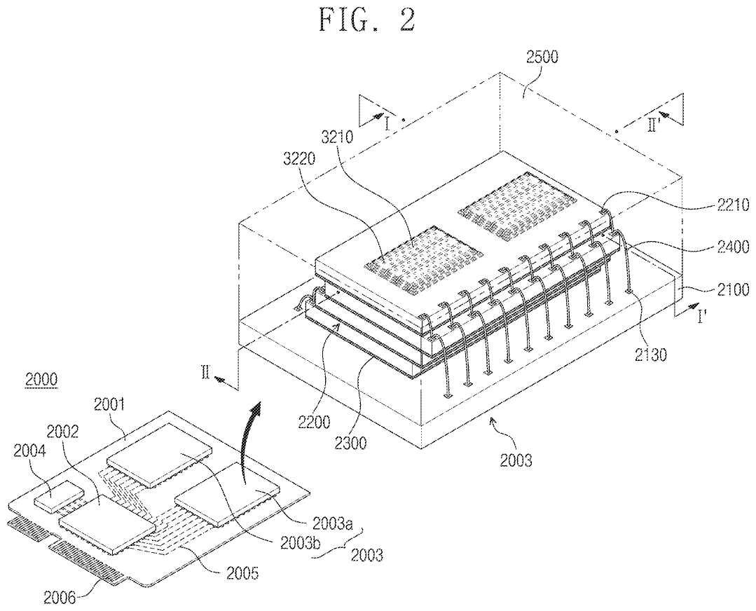

FIG. 2 illustrates a simplified perspective view showing an example of an electronic system including a three-dimensional semiconductor memory device.

Referring to FIG. 2, an electronic system 2000 may include a main board 2001, a controller 2002 mounted on the main board 2001, one or more semiconductor packages 2003, and a dynamic random access memory (DRAM) 2004. The semiconductor package 2003 and the DRAM 2004 may be connected to the controller 2002 through wiring patterns 2005 formed on the main board 2001.

The main board 2001 may include a connector 2006 including a plurality of pins that are coupled to an external host. The number and arrangement of the plurality of pins on the connector 2006 may be changed based on a communication interface between the electronic system 2000 and an external host. The electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In addition, the electronic system 2000 may operate with power supplied through the connector 2006 from an external host. The electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

The DRAM 2004 may be a buffer memory that reduces a difference in speed between the external host and the semiconductor package 2003 that serves as a data storage space. The DRAM 2004 included in the electronic system 2000 may operate as a kind of cache memory and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package 2003 may include first and second semiconductor packages 2003a and 2003b that are spaced apart from each other. Each of the first and second semiconductor packages 2003a and 2003b may include a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

The package substrate 2100 may be a printed circuit board including upper pads 2130. Each of the semiconductor chips 2200 may include one or more input/output pads 2210. The input/output pad 2210 may correspond to the input/output pad 1101 of FIG. 1. Each of the semiconductor chips 2200 may include gate stack structures 3210 and vertical channel structures 3220. Each of the semiconductor chips 2200 may include a three-dimensional semiconductor memory device.

For example, the connection structures 2400 may include bonding wires that electrically connect the input/output pads 2210 to the upper pads 2130. Therefore, in each of the first and second semiconductor packages 2003a and 2003b, the semiconductor chips 2200 may be electrically connected to each other in a wire bonding manner and may be electrically connected to the upper pads 2130 of the package substrate 2100. Alternatively, in each of the first and second semiconductor packages 2003a and 2003b, the semiconductor chips 2200 may be electrically connected to each other through connection structures such as through silicon vias (TSV) instead of the connection structures 2400 shaped like bonding wires.

For example, the controller 2002 and the semiconductor chips 2200 may be included in a single package. In some implementations, the controller 2002 and the semiconductor chips 2200 may be mounted on a separate interposer substrate other than the main board 2001 and may be electrically connected through wiring lines formed on the interposer substrate.

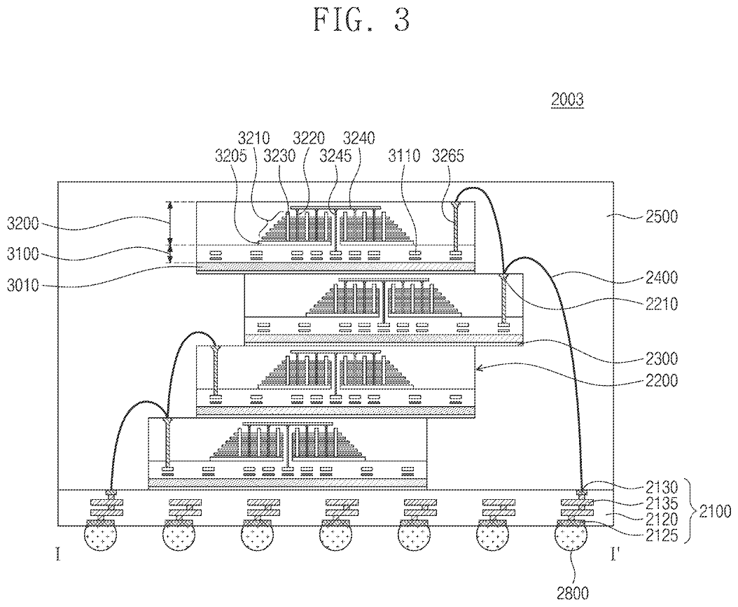

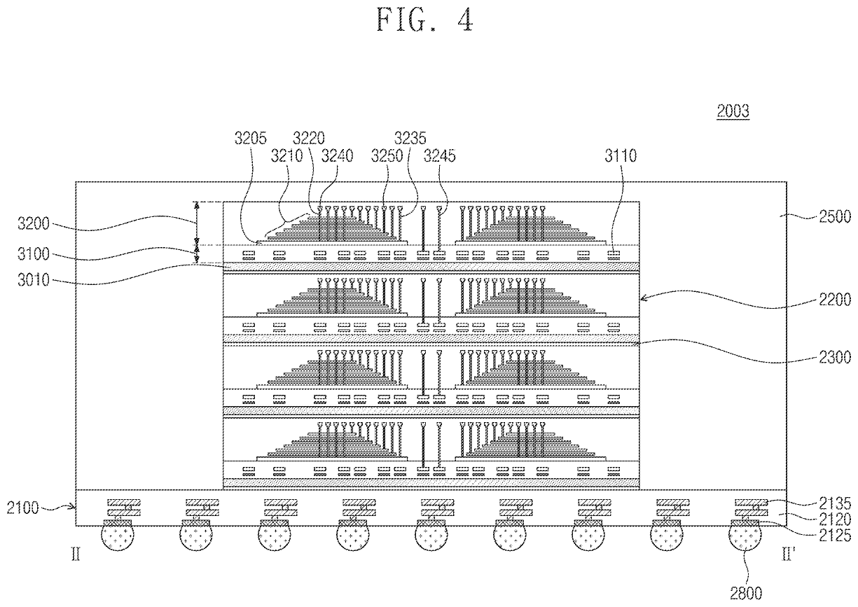

FIGS. 3 and 4 illustrate cross-sectional views respectively taken along lines I-I′and II-II′ of FIG. 2, showing a three-dimensional semiconductor memory device.

Referring to FIGS. 3 and 4, the semiconductor package 2003 may include a package substrate 2100, a plurality of semiconductor chips 2200 on the package substrate 2100, and a molding layer 2500 that covers the package substrate 2100 and the plurality of semiconductor chips 2200.

The package substrate 2100 may include a package substrate body 2120, upper pads 2130 disposed on a top surface of the package substrate body 2120, lower pads 2125 disposed or exposed on a bottom surface of the package substrate body 2120, and internal wiring lines 2135 that lie in the package substrate body 2120 and electrically connect the upper pads 2130 to the lower pads 2125. The upper pads 2130 may be electrically connected to a plurality of connection structures 2400. The lower pads 2125 may be connected through conductive connectors 2800 to the wiring patterns 2005 in the main board 2001 of the electronic system 2000 depicted in FIG. 2.

Each of the semiconductor chips 2200 may include a semiconductor substrate 3010 and may also include a first structure 3100 and a second structure 3200 that are sequentially stacked on the semiconductor substrate 3010. The first structure 3100 may include a peripheral circuit region including peripheral wiring lines 3110. The second structure 3200 may include a common source line 3205, a gate stack structure 3210 on the common source line 3205, vertical channel structures 3220 and separation structure 3230 that penetrate the gate stack structure 3210, bit lines 3240 electrically connected to the vertical channel structures 3220, gate connection lines 3235 and conductive lines 3250 that are electrically connected to word lines (see WL of FIG. 1) of the gate stack structure 3210.

Each of the semiconductor chips 2200 may include one or more through wiring lines 3245 that extend into the second structure 3200 and are electrically connected to the peripheral wiring lines 3110 of the first structure 3100. The through wiring line 3245 may penetrate the gate stack structure 3210 and may further be disposed outside the gate stack structure 3210. Each of the semiconductor chips 2200 may further include an input/output connection line 3265 that extends into the second structure 3200 and is electrically connected to the peripheral wiring lines 3110 of the first structure 3100, and may also further include input/output pads 2210 electrically connected to the input/output connection line 3265.

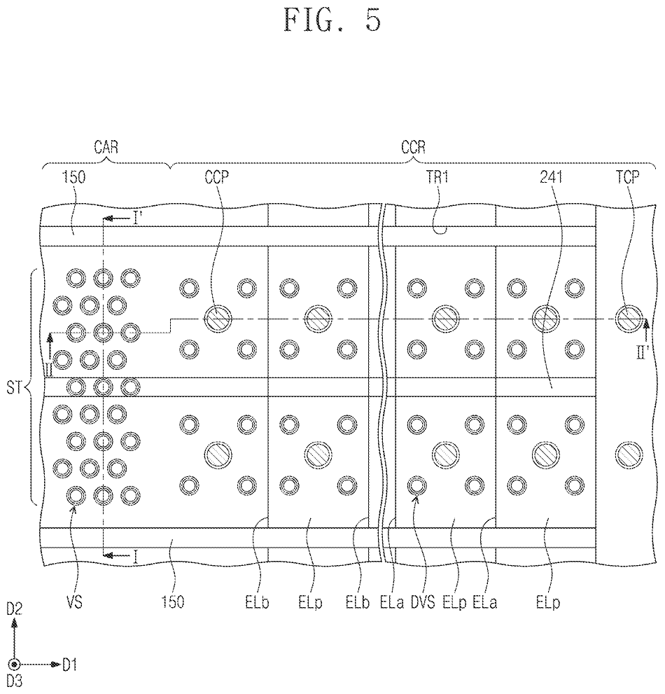

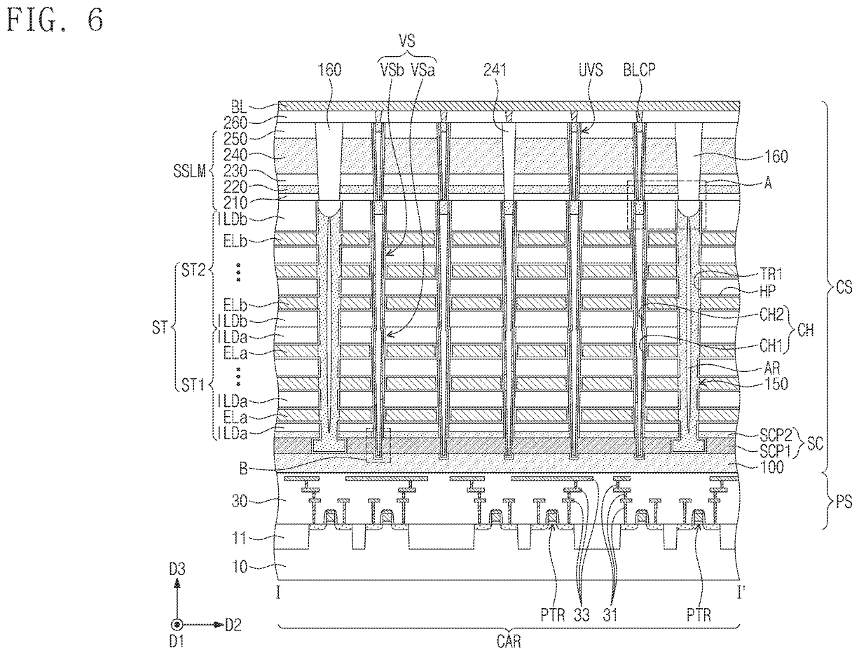

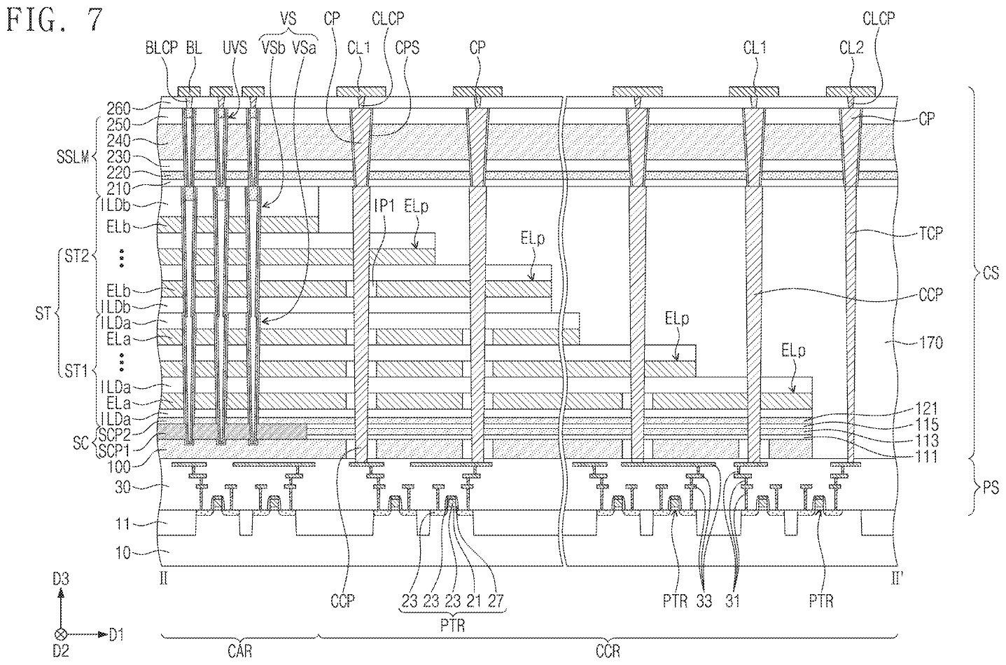

FIG. 5 illustrates a plan view showing an example of a three-dimensional semiconductor memory device. FIGS. 6 and 7 illustrate cross-sectional views respectively taken along lines I-I′ and II-II′ of FIG. 5, showing a three-dimensional semiconductor memory device.

Referring to FIGS. 5, 6, and 7, a three-dimensional semiconductor memory device may include a first substrate 10, a peripheral circuit structure PS on the first substrate 10, and a cell array structure CS on the peripheral circuit structure PS.

The first substrate 10 may include a cell array region CAR and a contact region CCR. The first substrate 10 may extend in a first direction D1 directed from the cell array region CAR toward the contact region CCR and in a second direction D2 that intersects the first direction D1. A top surface of the first substrate 10 may be parallel to the first direction D1 and the second direction D2 and may be perpendicular to a third direction D3 that intersects the first direction D1 and the second direction D2. For example, the first, second, and third directions D1, D2, and D3 may be orthogonal to each other.

From a plan view, the contact region CCR may extend in the first direction D1 from the cell array region CAR. The vertical channel structures VS and bit lines BL electrically connected to the vertical channel structures VS can be disposed in the cell array region CAR. The contact region CCR may be an area on which is provided a stepwise structure including pad portions ELp which will be discussed below. Alternatively, the contact region CCR may extend in the second direction D2 from the cell array region CAR.

The first substrate 10 may be, for example, a silicon substrate, a silicon-germanium substrate, a germanium substrate, or a monocrystalline epitaxial layer grown on a monocrystalline silicon substrate.

A device isolation layer 11 may be provided in the first substrate 10. The device isolation layer 11 may define an active section of the first substrate 10. For example, the device isolation layer 11 may include silicon oxide.

The peripheral circuit structure PS may be provided on the first substrate 10. The peripheral circuit structure PS may include peripheral circuit transistors PTR on the active section of the first substrate 10, peripheral contact plugs 31, peripheral circuit lines 33 electrically connected through the peripheral contact plugs 31 to the peripheral circuit transistors PTR, and a first dielectric layer 30 that surrounds the peripheral circuit transistors PTR, the peripheral contact plugs 31, and the peripheral circuit lines 33. The peripheral circuit structure PS may correspond to the first structure 1100F of FIG. 1, and the peripheral circuit lines 33 may correspond to the peripheral wiring lines 3110 of FIGS. 3 and 4.

A peripheral circuit may be constituted by the peripheral circuit transistors PTR, the peripheral contact plugs 31, and the peripheral circuit lines 33. For example, the peripheral circuit transistors PTR may constitute the decoder circuit 1110, the page buffer 1120, and the logic circuit 1130 of FIG. 1. In more detail, each of the peripheral circuit transistors PTR may include a peripheral gate dielectric layer 21, a peripheral gate electrode 23, a peripheral capping pattern 25, a peripheral gate spacer 27, and peripheral source/drain sections 29. In the implementations illustrated herein, the phrase source/drain section may be understood to mean a source terminal section or a drain terminal section of a transistor.

The peripheral gate dielectric layer 21 may be provided between the peripheral gate electrode 23 and the first substrate 10. The peripheral capping pattern 25 may be provided on the peripheral gate electrode 23. The peripheral gate spacer 27 may cover a sidewall of the peripheral gate dielectric layer 21, a sidewall of the peripheral gate electrode 23, and a sidewall of the peripheral capping pattern 25. The peripheral source/drain sections 29 may be provided in the first substrate 10 adjacent to opposite sides of the peripheral gate electrode 23.

The peripheral circuit lines 33 may be electrically connected through the peripheral contact plugs 31 to the peripheral circuit transistors PTR. Each of the peripheral circuit transistors PTR may be, for example, an NMOS transistor, a PMOS transistor, or a gate-all-around type transistor. For example, the peripheral contact plugs 31 may each have a width in the first direction D1 or the second direction D2 that increases with increasing distance from the first substrate 10. The peripheral contact plugs 31 and the peripheral circuit lines 33 may include a conductive material, such as metal.

The first dielectric layer 30 may be disposed on the top surface of first substrate 10. On the first substrate 10, the first dielectric layer 30 may cover the peripheral circuit transistors PTR, the peripheral contact plugs 31, and the peripheral circuit lines 33. The first dielectric layer 30 may include a plurality of dielectric layers that constitute a multi-layered structure. For example, the first dielectric layer 30 may include one or more of silicon oxide, silicon nitride, silicon oxynitride, and low-k dielectric materials.

The first dielectric layer 30 may be provided in the cell array region CAR with the cell array structure CS that includes a second substrate 100 and a stack structure ST on the second substrate 100. The second substrate 100 may extend in the first and second directions D1 and D2. The second substrate 100 may not be provided on a portion of the contact region CCR. The second substrate 100 may be a semiconductor substrate including a semiconductor material. The second substrate 100 may include, for example, silicon (Si), germanium (Ge), silicon germanium (SiGe), gallium arsenic (GaAs), indium gallium arsenic (InGaAs), aluminum gallium arsenic (AlGaAs), or a mixture thereof.

The stack structure ST may be provided on the second substrate 100. The stack structure ST may extend from the cell array region CAR toward the contact region CCR. The stack structure ST may correspond to the gate stack structures 3210 of FIGS. 3 and 4. The stack structure ST may be provided in plural, and the plurality of stack structures ST may be arranged along the second direction D2 and spaced apart in the second direction D2 from each other across a separation structure 150 which will be discussed below. For convenience of description, the following explanation will focus on a single stack structure ST, but this explanation may also be applicable to other stack structures ST.

The stack structure ST may include interlayer dielectric layers ILDa and ILDb and gate electrodes ELa and ELb that are alternately stacked. The gate electrodes ELa and ELb may correspond to the first and second gate lower lines LL1 and LL2, and the first and second gate upper lines UL1 and UL2, and the word lines WL of FIG. 1.

The stack structure ST may include a first stack structure ST1 on the second substrate 100 and a second stack structure ST2 on the first stack structure ST1. The first stack structure ST1 may include first interlayer dielectric layers ILDa and first gate electrodes ELa that are alternately stacked, and the second stack structure ST2 may include second interlayer dielectric layers ILDb and second gate electrodes ELb that are alternately stacked. The first and second gate electrodes ELa and ELb may have substantially the same thickness in the third direction D3.

The first and second gate electrodes ELa and ELb may have their lengths in the first direction D1 that decrease in the third direction D3 departing from the second substrate 100. For example, each of the first and second gate electrodes ELa and ELb may have a length in the first direction D1 that is greater than a length in the first direction D1 of an immediately overlying gate electrode. A lowermost one of the first gate electrodes ELa in the first stack structure ST1 may have a maximum length in the first direction D1, and an uppermost one of the second gate electrodes ELb in the second stack structure ST2 may have a minimum length in the first direction D1.

The first and second gate electrodes ELa and ELb may have the pad portions ELp on the contact region CCR. The pad portions ELp of the first and second gate electrodes ELa and ELb may be disposed at their positions that are horizontally and vertically different from each other. The pad portions ELp may constitute a stepwise structure along the first direction D1.

The stepwise structure may be arranged such that each of the first and second stack structures ST1 and ST2 may have a thickness that decreases with increasing distance from an outermost one of vertical channel structures VS which will be discussed below, and such that the first and second gate electrodes ELa and ELb may have their sidewalls spaced apart at a regular interval from each other along the first direction D1 from a plan view. For example, the first and second gate electrodes ELa and ELb may include at least one selected from doped semiconductors (e.g., doped silicon), metals (e.g., tungsten, copper, aluminum), conductive metal nitrides (e.g., titanium nitride and tantalum nitride), and transition metals (e.g., titanium and tantalum), and for example may include tungsten.

The first and second interlayer dielectric layers ILDa and ILDb may be provided between the first and second gate electrodes ELa and ELb, and each of the first and second interlayer dielectric layers ILDa and ILDb may have a sidewall aligned with that of an underlying one of the first and second gate electrodes ELa and ELb. For example, likewise the first and second gate electrodes ELa and ELb, the first and second interlayer dielectric layers ILDa and ILDb may have their lengths in the first direction D1 that decrease with increasing distance from the second substrate 100.

A lowermost one of the second interlayer dielectric layers ILDb may contact an uppermost one of the first interlayer dielectric layers ILDa. For example, each of the first and second interlayer dielectric layers ILDa and ILDb may have a thickness less than that of each of the first and second gate electrodes ELa and ELb. For example, a lowermost one of the first interlayer dielectric layers ILDa may have a thickness less than that of each of other first and second interlayer dielectric layers ILDa and ILDb. For example, an uppermost one of the second interlayer dielectric layers ILDb may have a thickness greater than that of each of other first and second interlayer dielectric layers ILDa and ILDb.

Except the lowermost first interlayer dielectric layer ILDa and the uppermost second interlayer dielectric layer ILDb, other first and second interlayer dielectric layers ILDa and ILDb may have substantially the same thickness. The present inventive concepts, however, are not limited thereto. The first and second interlayer dielectric layers ILDa and ILDb may have their thicknesses depend on properties of a semiconductor device.

For example, the first and second interlayer dielectric layers ILDa and ILDb may include one or more of silicon oxide, silicon nitride, silicon oxynitride, low-k dielectric materials, high-density plasma (HDP) oxide, and tetraethylorthosilicate (TEOS).

Alternatively, the first and second stack structures ST1 and ST2 may have different stepwise structures on the contact region CCR. For example, a length in the first direction D1 of a lowermost one of the second gate electrodes ELb in the second stack structure ST2 may be substantially the same as a length in the first direction D1 of the lowermost one of the first gate electrodes ELa in the first stack structure ST1. The lowermost one of the second gate electrodes ELb in the second stack structure ST2 may be longer in the first direction D1 than the uppermost one of the first gate electrodes ELa in the first stack structure ST1.

A source structure SC may be provided between the stack structure ST and the second substrate 100 on the cell array region CAR. The source structure SC may correspond to the common source line CSL of FIG. 1 or the common source line 3205 of FIGS. 3 and 4. The source structure SC may include a first source conductive pattern SCP1 and a second source conductive pattern SCP2 that are sequentially stacked on the second substrate 100. The second source conductive pattern SCP2 may be provided between the first source conductive pattern SCP1 and the lowermost one of the first interlayer dielectric layers ILDa. The first source conductive pattern SCP1 may have a thickness greater than that of the second source conductive pattern SCP2. The first and second source conductive patterns SCP1 and SCP2 may include a semiconductor material such as silicon or a semiconductor material doped with impurities. When the first and second source conductive patterns SCP1 and SCP2 include an impurity-doped semiconductor material, the first source conductive pattern SCP1 may have an impurity concentration greater than that of the second source conductive pattern SCP2.

The first source conductive pattern SCP1 of the source structure SC may be provided only on the cell array region CAR and may not be provided on the contact region CCR. The second source conductive pattern SCP2 of the source structure SC may extend from the cell array region CAR toward the contact region CCR. For example, the second source conductive pattern SCP2 on the cell array region CAR may be substantially the same as a semiconductor layer 121 on the contact region CCR which will be discussed below.

First, second, and third buffer dielectric layers 111, 113, and 115 and a semiconductor layer 121 may be provided between the lowermost one of the first interlayer dielectric layers ILDa and the second substrate 100 on the contact region CCR. The first, second, and third buffer dielectric layers 111, 113, and 115 and the semiconductor layer 121 may be sequentially stacked on the second substrate 100. The second buffer dielectric layer 113 may include a dielectric material different from that of the first and third buffer dielectric layers 111 and 115. The second buffer dielectric layer 113 may be thicker than the first and third buffer dielectric layers 111 and 115, but the present disclosure is not limited thereto. The first, second, and third buffer dielectric layers 111, 113, and 115 may include, for example, at least one selected from silicon oxide, silicon nitride, silicon oxynitride, silicon carbide, and silicon-germanium.

On the cell array region CAR, a plurality of vertical channel structures VS may be provided to penetrate the stack structure ST and the source structure SC. The vertical channel structures VS may penetrate at least a portion of the second substrate 100, and each of the vertical channel structures VS may have a bottom surface located at a lower level than that of a top surface of the second substrate 100 and that of a bottom surface of the source structure SC. For example, the vertical channel structures VS may directly contact the second substrate 100.

From a plan view, the vertical channel structures VS may be arranged in a zigzag fashion in the first direction D1 or the second direction D2. The vertical channel structures VS may not be provided on the contact region CCR. The vertical channel structures VS may correspond to the vertical channel structures 3220 of FIGS. 2 to 4. The vertical channel structures VS may correspond to channels of the lower transistors LT1 and LT2, the upper transistors UT1 and UT2, and the memory cell transistors MCT depicted in FIG. 1.

The vertical channel structures VS may be provided in vertical channel holes CH that penetrate the stack structure ST. Each of the vertical channel holes CH may include a first vertical channel hole CH1 that penetrates the first stack structure ST1 and a second vertical channel hole CH2 that penetrates the second stack structure ST2. The first and second vertical channel holes CH1 and CH2 of each of the vertical channel holes CH may be connected to each other in the third direction D3.

Each of the vertical channel structures VS may include a first vertical channel structure VSa and a second vertical channel structure VSb. The first vertical channel structure VSa may be provided in the first vertical channel hole CH1, and the second vertical channel structure VSb may be provided in the second vertical channel hole CH2. The second vertical channel structure VSb may be provided on and connected to the first vertical channel structure VSa.

For example, each of the first and second vertical channel structures VSa and VSb may have a width in the first direction D1 or the second direction D2, and the width of each of the first and second vertical channel structures VSa and VSb may increase in the third direction D3. A width at an uppermost portion of the first vertical channel structure VSa may be greater than a width at a lowermost portion of the second vertical channel structure VSb. For example, each of the vertical channel structures VS may have a sidewall that has a step difference at a boundary between the first vertical channel structure VSa and the second vertical channel structure VSb. The present inventive concepts, however, are not limited thereto, and each of the vertical channel structures VS may have a sidewall that has three or more step differences at different levels or is flat with no step difference.

On the contact region CCR, a second dielectric layer 170 may be provided to cover the stack structure ST and a portion of the first dielectric layer 30. For example, the second dielectric layer 170 may be provided on the pad portions ELp of the first and second gate electrodes ELa and ELb, while covering the stepwise structure of the stack structure ST. The second dielectric layer 170 may have a top surface that is substantially planarized. The top surface of the second dielectric layer 170 may be substantially coplanar with that of the stack structure ST. For example, the top surface of the second dielectric layer 170 may be substantially coplanar with that of the uppermost one of the second interlayer dielectric layers ILDb in the stack structure ST.

The second dielectric layer 170 may include a single or a plurality of stacked dielectric layers. For example, the second dielectric layer 170 may include one or more of silicon oxide, silicon nitride, silicon oxynitride, and low-k dielectric materials. The second dielectric layer 170 may include a dielectric material different from that of the first and second interlayer dielectric layers ILDa and ILDb of the stack structure ST. For example, when the first and second interlayer dielectric layers ILDa and ILDb of the stack structure ST include high-density plasma oxide, the second dielectric layer 170 may include tetraethylorthosilicate (TEOS).

Dummy vertical channel structures DVS may be provided around cell contact plugs CCP which will be discussed. The dummy vertical channel structures DVS may not be provided on the cell array region CAR. The dummy vertical channel structures DVS and the vertical channel structures VS may be formed simultaneously with each other and may have substantially the same structure. For example, on the contact region CCR, the dummy vertical channel structures DVS may penetrate the second dielectric layer 170 and the stack structure ST. Alternatively, the vertical channel structures VS and the dummy vertical channel structures DVS may not be formed simultaneously with each other, or the dummy vertical channel structures DVS may not be provided.

Cell contact plugs CCP may be provided to penetrate the second dielectric layer 170 to be connected to the first and second gate electrodes ELa and ELb. Each of the cell contact plugs CCP may penetrate one of the first and second interlayer dielectric layers ILDa and ILDb to come into contact with one of the pad portions ELp of the first and second gate electrodes ELa and ELb. The cell contact plugs CCP may correspond to the gate connection lines of FIGS. 3 and 4.

Each of the cell contact plugs CCP may be spaced apart in a horizontal direction and electrically separated from the first and second gate electrodes ELa and ELb below the pad portions ELp across a first dielectric pattern IP1, which horizontal direction is one direction on a plane parallel to the first direction D1 and the second direction D2. Each of the cell contact plugs CCP may be spaced apart in the horizontal direction and electrically separated from the second substrate 100 across a second dielectric pattern IP2. The first and second dielectric patterns IP1 and IP2 may include the same material as that of the first and second interlayer dielectric layers ILDa and ILDb of the stack structure ST. Each of the cell contact plugs CCP may have a bottom surface located at a level lower than that of a bottom surface of the second substrate 100. A height in the third direction D3 of each of the cell contact plugs CCP may be substantially the same as a height in the third direction D3 of a peripheral contact plug TCP, which will be discussed below.

A peripheral contact plug TCP may be provided to penetrate the second dielectric layer 170 and at least a portion of the first dielectric layer 30 to be electrically connected to the peripheral circuit transistors PTR of the peripheral circuit structure PS. Alternatively, the peripheral contact plug TCP may be provided in plural. The peripheral contact plug TCP may be spaced apart in the first direction D1 from the second substrate 100, the source structure SC, and the stack structure ST. The peripheral contact plug TCP may correspond to the through wiring line 3245 of FIG. 3.

The cell contact plugs CCP and the peripheral contact plug TCP may each include a conductive pattern including at least one metal selected from aluminum, copper, tungsten, molybdenum, and cobalt, and may also include a barrier pattern including a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

When the stack structure ST is provided in plural, a separation structure 150 may be provided in a first trench TR1 that runs in the first direction D1 across between the plurality of stack structures ST. The first trench TR1 may extend along the first direction D1 from the cell array region CAR toward the contact region CCR of the first substrate 10. The separation structure 150 may be spaced apart in the second direction D2 from the vertical channel structures VS. For example, the separation structure 150 may have a top surface located at a level the same as that of top surfaces of the vertical channel structures VS. The separation structure 150 may have a bottom surface located at a level substantially the same as that of a bottom surface of the first source conductive pattern SCP1.

The separation structure 150 may have a seam AR therein. The seam AR may be positioned at a center of the separation structure 150. The separation structure 150 may be provided in plural, and the plurality of separation structures 150 may be spaced apart in the second direction D2 from each other across the stack structure ST. Thus, the stack structure ST may be positioned between the plurality of separation structures 150.

An interfacial dielectric layer HP may be provided between the first gate electrodes ELa and the first interlayer dielectric layers ILDa and between the second gate electrodes ELb and the second interlayer dielectric layers ILDb. The interfacial dielectric layer HP may extend between the vertical channel structures VS and the first and second gate electrodes ELa and ELb. The interfacial dielectric layer HP may extend between the separation structure 150 and the first and second interlayer dielectric layers ILDa and ILDb. The interfacial dielectric layer HP may cover a lower portion of the separation structure 150. For example, the interfacial dielectric layer HP may include a metal oxide layer, such as an aluminum oxide layer or a hafnium oxide layer.

A selection mold structure SSLM, a third dielectric layer 260, and bit lines BL may be provided on the second dielectric layer 170 and the stack structure ST. The selection mold structure SSLM may include a first capping dielectric layer 210, a second capping dielectric layer 220, a third capping dielectric layer 230, a selection semiconductor layer 240, and a mold dielectric layer 250 that are sequentially stacked. The first capping dielectric layer 210 may cover the top surface of the second dielectric layer 170, the top surface of the uppermost one of the second interlayer dielectric layers ILDb in the stack structure ST, and the top surfaces of the vertical channel structures VS.

The first capping dielectric layer 210, the second capping dielectric layer 220, the third capping dielectric layer 230, the mold dielectric layer 250, and the third dielectric layer 260 may each include a single dielectric layer or a plurality of stacked dielectric layers. The first capping dielectric layer 210, the third capping dielectric layer 230, the mold dielectric layer 250, and the third dielectric layer 260 may each include substantially the same dielectric material. For example, the first capping dielectric layer 210, the second capping dielectric layer 220, the third capping dielectric layer 230, the mold dielectric layer 250, and the third dielectric layer 260 may each include one or more of silicon oxide, silicon oxynitride, and low-k dielectric materials. The selection semiconductor layer 240 may include polycrystalline silicon.

On the cell array region CAR, a plurality of upper vertical channel structures UVS may be provided to penetrate the selection mold structure SSLM. The upper vertical channel structure UVS may overlap vertically (or in the third direction D3) with the vertical channel structure VS. From a plan view, as the upper vertical channel structures UVS are located at positions substantially the same as those of corresponding vertical channel structures VS, the upper vertical channel structures UVS may be arranged in a zigzag fashion along the first direction D1 or the second direction D2. The upper vertical channel structures UVS may be electrically connected to the vertical channel structures VS. The upper vertical channel structures UVS may have top surfaces coplanar with that of the mold dielectric layer 250. The upper vertical channel structures UVS may have bottom surfaces coplanar with that of the first capping dielectric layer 210. For example, each of the upper vertical channel structures UVS may have a thickness substantially the same as that of the selection mold structure SSLM. The upper vertical channel structures UVS may not be provided on the contact region CCR.

A separation dielectric pattern 241 may be provided to penetrate in the third direction D3 through the selection semiconductor layer 240 and to run in the first direction D1 across the selection semiconductor layer 240. The separation dielectric pattern 241 may extend in the first direction D1. The upper vertical channel structure UVS may not be provided on an area where the separation dielectric pattern 241 is provided. For example, the separation dielectric pattern 241 may be spaced apart in the second direction D2 from the upper vertical channel structure UVS. The separation dielectric pattern 241 may have a thickness substantially the same as that of the upper vertical channel structure UVS. The separation dielectric pattern 241 may penetrate the first, second, and third capping dielectric layers 210, 220, and 230 and the mold dielectric layer 250. Alternatively, the thickness of the separation dielectric pattern 241 may be substantially the same as that of the selection semiconductor layer 240. In this case, the separation dielectric pattern 241 may not penetrate any of the first, second, and third capping dielectric layers 210, 220, and 230 and the mold dielectric layer 250, and may penetrate only the selection semiconductor layer 240.

Between two separation structures 150 spaced apart from each other in the second direction D2, the separation dielectric pattern 241 may separate the selection semiconductor layer 240 in the second direction D2. For example, the separation dielectric pattern 241 may serve to separate a string selection line of a three-dimensional NAND Flash memory device. The separation dielectric pattern 241 may include a dielectric material, such as one or more of silicon oxide, silicon nitride, and silicon oxynitride.

The stack structure ST may be provided on the peripheral circuit structure PS with an upper separation structure 160 that penetrates the selection mold structure SSLM. The upper separation structure 160 may overlap vertically (e.g., in the third direction D3) with the separation structure 150, while contacting the separation structure 150. From a plan view, the upper separation structure 160 may be provided at a same position as the separation structure 150. For example, the upper separation structure 160 may extend in the first direction D1. The upper separation structure 160 may penetrate the first, second, and third capping dielectric layers 210, 220, and 230, the selection semiconductor layer 240, and the mold dielectric layer 250 that are included in the selection mold structure SSLM. The upper separation structure 160 may have a thickness substantially the same as that of the selection mold structure SSLM. The upper separation structure 160 may have a width in the first direction D1 or the second direction D2, and the width of the upper separation structure 160 may increase in the third direction D3. Likewise, the separation dielectric pattern 241, the upper separation structure 160 may include a dielectric material, such as one or more of silicon oxide, silicon nitride, and silicon oxynitride.

On the contact region CCR, contact plugs CP may be provided to penetrate the selection mold structure SSLM. Each of the contact plugs CP may be electrically connected to the cell contact plug CCP or the peripheral contact plug TCP. Each of the contact plugs CP may be disposed on and overlap vertically (e.g., in the third direction D3) with the cell contact plug CCP or the peripheral contact plug TCP.

Spacer dielectric layers CPS may be provided to surround the contact plugs CP. The spacer dielectric layers CPS may be positioned between the selection mold structure SSLM and sidewalls of the contact plugs CP. The spacer dielectric layers CPS may electrically insulate the contact plugs CP from the selection semiconductor layer 240.

On the cell array region CAR, bit-line contact plugs BLCP may be provided to penetrate the third dielectric layer 260 to come into electrical connection with the upper vertical channel structures UVS. On the contact region CCR, conductive line contact plugs CLCP may be provided to penetrate the third dielectric layer 260 to come into electrical connection with the contact plugs CP. The bit-line contact plugs BLCP and the conductive line contact plugs CLCP may include a metallic material, such as tungsten.

The bit lines BL may be provided on the third dielectric layer 260 to come into connection with the bit-line contact plugs BLCP. The bit lines BL may correspond to the bit lines BL of FIG. 1 and/or the bit lines 3240 of FIGS. 3 and 4.

The third dielectric layer 260 may contact first conductive lines CL1 and second conductive lines CL2 that are connected to the conductive line contact plugs CLCP. The first conductive lines CL1 may be electrically connected to the cell contact plugs CCP through the contact plugs CP that correspond to the first conductive lines CL1. The second conductive lines CL2 may be electrically connected to the peripheral contact plug TCP through contact plugs CP that correspond to the second conductive lines CL2. The first and second conductive lines CL1 and CL2 may correspond to the conductive lines 3250 of FIGS. 3 and 4.

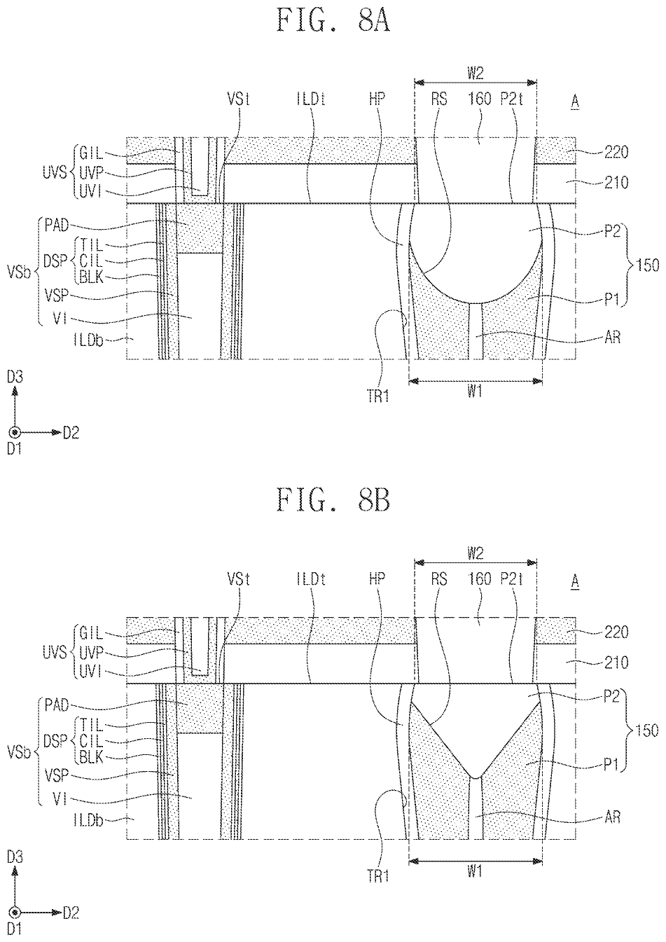

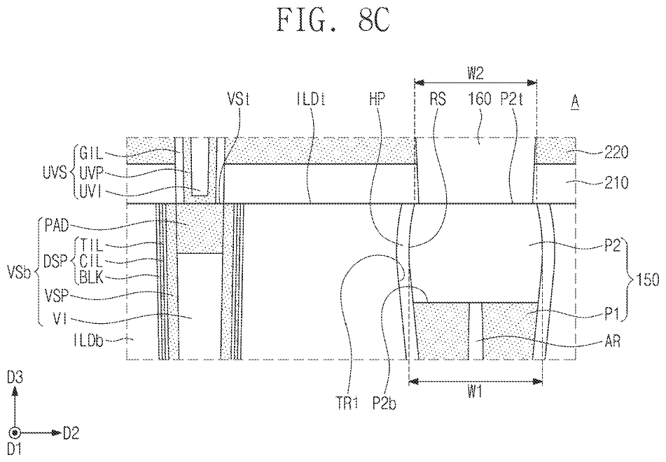

FIGS. 8A to 8C illustrate enlarged cross-sectional views of section A depicted in FIG. 6, partially showing a three-dimensional semiconductor memory device.

Referring to FIGS. 8A to 8C, the second vertical channel structure VSb may include a data storage pattern DSP and a vertical semiconductor pattern VSP that are sequentially provided on an inner sidewall of the second vertical channel hole CH2, a buried dielectric pattern VI that fills an inner space surrounded by the vertical semiconductor pattern VSP, and a conductive pad PAD on the buried dielectric pattern VI.

The data storage pattern DSP may include a blocking dielectric layer BLK, a charge storage layer CIL, and a tunneling dielectric layer TIL that are sequentially stacked on the inner sidewall of the second vertical channel hole CH2. The blocking dielectric layer BLK may be adjacent to the second interlayer dielectric layer ILDb, and the tunneling dielectric layer TIL may be adjacent to the vertical semiconductor pattern VSP. The charge storage layer CIL may be positioned between the blocking dielectric layer BLK and the tunneling dielectric layer TIL. The blocking dielectric layer BLK may cover the inner sidewall of the second vertical channel hole CH2.

The blocking dielectric layer BLK, the charge storage layer CIL, and the tunneling dielectric layer TIL may extend in the third direction D3 between the second interlayer dielectric layer ILDb and the vertical semiconductor pattern VSP. The data storage pattern DSP may store and/or change data by using Fowler-Nordheim tunneling induced by a voltage difference between the vertical semiconductor pattern VSP and the first and second gate electrodes ELa and ELb of FIG. 6. For example, the blocking dielectric layer BLK and the tunneling dielectric layer TIL may include silicon oxide, and the charge storage layer CIL may include silicon nitride or silicon oxynitride.

The conductive pad PAD may be provided in a space surrounded by the buried dielectric pattern VI and the data storage pattern DSP (or the vertical semiconductor pattern VSP). From a plan view, a top surface VSt of the second vertical channel structure VSb may have a circular shape, an oval shape, or a bar shape. The data storage pattern DSP may cover a sidewall of the second interlayer dielectric layer ILDb. The vertical semiconductor pattern VSP may conformally cover an inner sidewall of the data storage pattern DSP.

The vertical semiconductor pattern VSP may be provided between the data storage pattern DSP and the buried dielectric pattern VI. The vertical semiconductor pattern VSP may have a tubular shape or a pipe shape whose bottom end is closed. The data storage pattern DSP may have a tubular shape or a pipe shape whose bottom end is opened.

The vertical semiconductor pattern VSP may include, for example, an impurity-doped semiconductor material, an impurity-undoped intrinsic semiconductor material, or a polycrystalline semiconductor material. The conductive pad PAD may include an impurity-doped semiconductor material or a conductive material.

The upper vertical channel structure UVS may be provided on the second vertical channel structure VSb. The upper vertical channel structure UVS may include an upper channel pattern UVP, a selection gate dielectric pattern GIL that surrounds a sidewall of the upper channel pattern UVP, and an upper buried dielectric pattern UVI that fills an inside of the upper channel pattern UVP. The upper channel pattern UVP of the upper vertical channel structure UVS may be in contact with the conductive pad PAD of the second vertical channel structure VSb. The upper vertical channel structure UVS may further include an upper pad on the upper buried dielectric pattern UVI.

The upper channel pattern UVP may include a semiconductor material and may be used as channels of the upper transistors UT1 and UT2 discussed in FIG. 1. The upper channel pattern UVP may have a tubular shape or a pipe shape whose bottom end is closed. The selection gate dielectric pattern GIL may be formed of a single layer, and may include one or more of silicon oxide, silicon oxynitride, and high-k dielectric materials.

The separation structure 150 may include a first portion P1 and a second portion P2. The first portion P1 may be provided on an inner sidewall and a bottom surface of the first trench TR1 depicted in FIG. 6. The first portion P1 may be positioned below the second portion P2. For example, the first portion P1 may be positioned between the second portion P2 and the second substrate 100 of FIG. 6.

The second portion P2 may be provided in a recess RS of the separation structure 150 and may be positioned between the first portion P1 and the upper separation structure 160. As the recess RS is positioned in the second interlayer dielectric layer ILDb, the second portion P2 may be provided in an uppermost one of the interlayer dielectric layers ILDa and ILDb. The second portion P2 may have a shape that is changed in accordance with a shape of the recess RS. Referring to FIG. 8A, the bottom of the second portion P2 may have a shape that is convex toward the second substrate 100 of FIG. 6 (e.g., the surface of the second portion P2 facing toward the second substrate 100 of FIG. 6 is convex). Referring to FIG. 8B, the second portion P2 may have bottom surfaces that is inclined with respect to the third direction D3. For example, the second portion P2 may have a wedge shape. Referring to FIG. 8C, a bottom surface P2b of the second portion P2 may be parallel to a top surface P2t of the second portion P2. The bottom surface P2b of the second portion P2 may be parallel to the first and second directions D1 and D2.

The top surface P2t of the second portion P2 may be located at a level substantially the same as that of the top surface VSt of the second vertical channel structure VSb. The top surface P2t of the second portion P2 may be located at a level substantially the same as that of a top surface ILDt of the second interlayer dielectric layer ILDb. In this description, the top surface P2t of the second portion P2 may be the same as the top surface of the separation structure 150, the top surface VSt of the second vertical channel structure VSb may be the same as the top surface of the vertical channel structure VS depicted in FIG. 6, and the top surface ILDt of the second interlayer dielectric layer ILDb may be the same as the top surface of the stack structure ST depicted in FIG. 6 and a top surface of the uppermost one of the interlayer dielectric layers ILDa and ILDb. For example, the top surface of the separation structure 150 may be located at a level substantially the same as that of the top surface of the vertical channel structure VS depicted in FIG. 6 and that of the top surface of the uppermost one of the interlayer dielectric layers ILDa and ILDb depicted in FIG. 6.

The separation structure 150 may have a first width W1 at a level lower than that of the top surface P2t of the second portion P2. The separation structure 150 may have a second width W2 on the top surface P2t of the second portion P2. The first width W1 may be greater than the second width W2. The first width W1 may be a maximum width of the separation structure 150. For example, a width of the separation structure 150 may not have a maximum value at the top surface of the separation structure 150. The separation structure 150 may have a high aspect ratio to cause a bowing phenomenon. Therefore, the first portion P1 may have the seam AR therein. The seam AR may be positioned at a center in the second direction D2 of the first portion P1. As the second portion P2 is formed in the recess RS after the first portion P1 is formed, the second portion P2 may cover the seam AR of the first portion P1. The second portion P2 may contact the seam AR of the first portion P1.

The first and second portions P1 and P2 of the separation structure 150 may include a dielectric material. For example, the dielectric material may include one or more of silicon oxide, silicon nitride, and silicon oxynitride. The first portion P1 and the second portion P2 may include different dielectric materials from each other. For example, the first portion P1 may include silicon nitride, and the second portion P2 may include silicon oxide.

The interfacial dielectric layer HP may be positioned between the separation structure 150 and the second interlayer dielectric layer ILDb. The interfacial dielectric layer HP may contact the first portion P1 and the second portion P2 of the separation structure 150. The interfacial dielectric layer HP may cover the inner wall of the first trench TR1, while having a constant thickness in the second direction D2.

An etching process may be performed to form the recess RS of the separation structure 150. For example, the etching process may be a wet etching process that does not use fluorine. Thus, the first and second gate electrodes ELa and ELb of the stack structure ST depicted in FIG. 6 may be prevented from degradation with fluorine through the separation structure 150. In addition, because the first capping dielectric layer 210 on the separation structure 150 includes silicon oxide, and because the second portion P2 in contact with the upper separation structure 160 includes silicon oxide, no subsequent process may be changed. In conclusion, the three-dimensional semiconductor memory device may improve in reliability and electrical properties without changing a subsequent process.

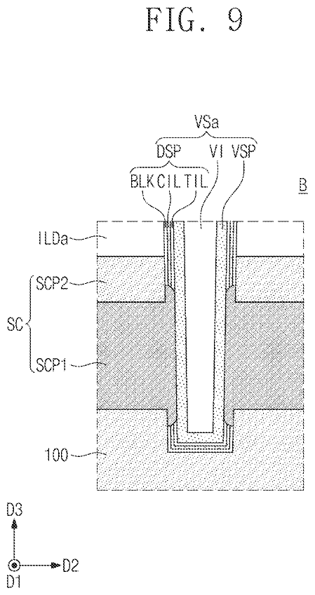

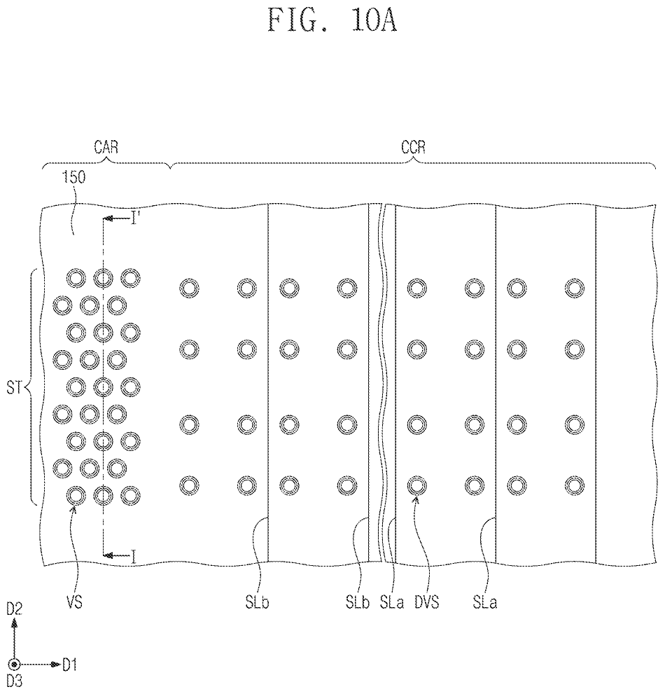

FIG. 9 illustrates an enlarged cross-sectional view of section B depicted in FIG. 6, partially showing a three-dimensional semiconductor memory device.

Referring to FIG. 9, each of first vertical channel structures VSa may include a data storage pattern DSP, a vertical semiconductor pattern VSP, a buried dielectric pattern VI, and a vertical semiconductor pattern VSP.

The data storage pattern DSP may include a blocking dielectric layer BLK, a charge storage layer CIL, and a tunneling dielectric layer TIL that are sequentially stacked. The blocking dielectric layer BLK may be adjacent to the first interlayer dielectric layer ILDa, and the tunneling dielectric layer TIL may be adjacent to the vertical semiconductor pattern VSP. The charge storage layer CIL may be positioned between the blocking dielectric layer BLK and the tunneling dielectric layer TIL. The blocking dielectric layer BLK may cover an inner sidewall of the first vertical channel hole CH1.

The first vertical channel structure VSa may have a structure substantially the same as that of the second vertical channel structure VSb discussed in FIGS. 8A to 8C.

The first source conductive pattern SCP1 of the source structure SC may be in contact with the vertical semiconductor pattern VSP, and the second source conductive pattern SCP2 of the source structure SC may be spaced apart from the vertical semiconductor pattern VSP across the data storage pattern DSP. The first source conductive pattern SCP1 may be spaced apart from the buried dielectric pattern VI across the vertical semiconductor pattern VSP. The first source conductive pattern SCP1 may include a protrusion located at a level higher than that of a bottom surface of the second source conductive pattern SCP2 and a protrusion located at a level lower than that of a bottom surface of the first source conductive pattern SCP1. The protrusions of the first source conductive pattern SCP1 may be located at a level lower than that of a top surface of the second source conductive pattern SCP2. For example, the protrusions may have curved shapes at surfaces in contact with the data storage pattern DSP.

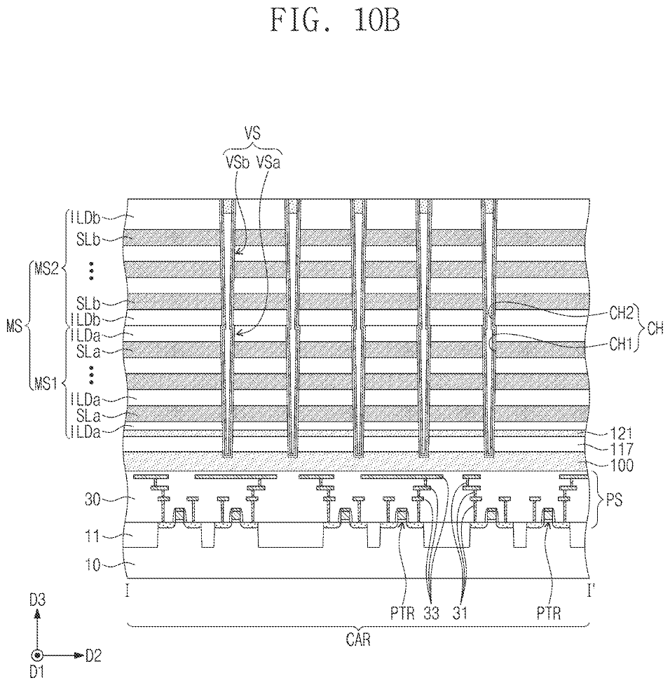

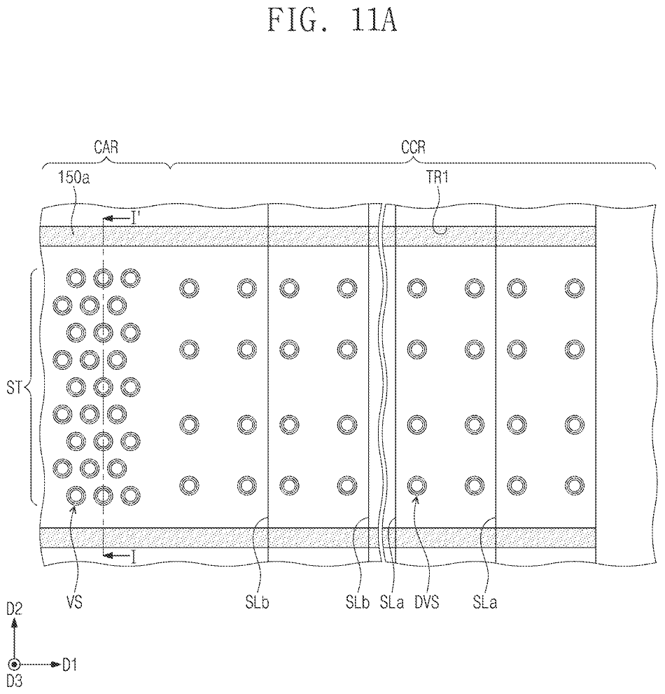

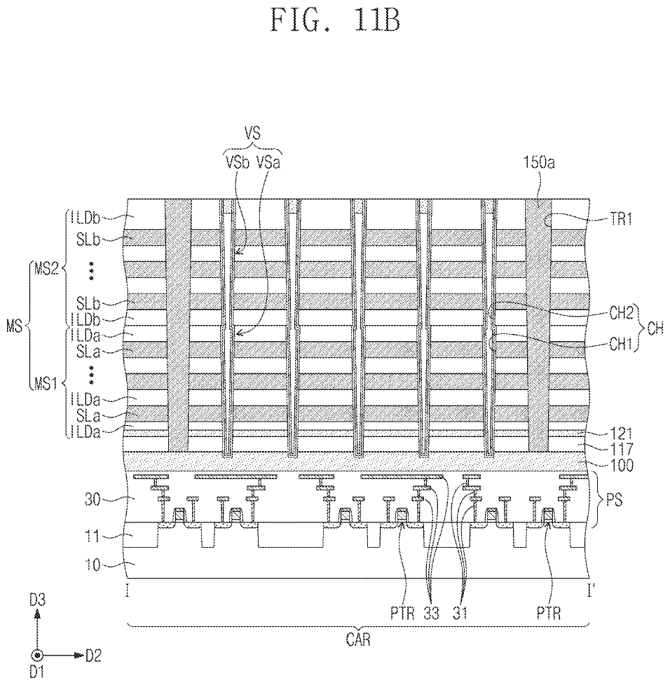

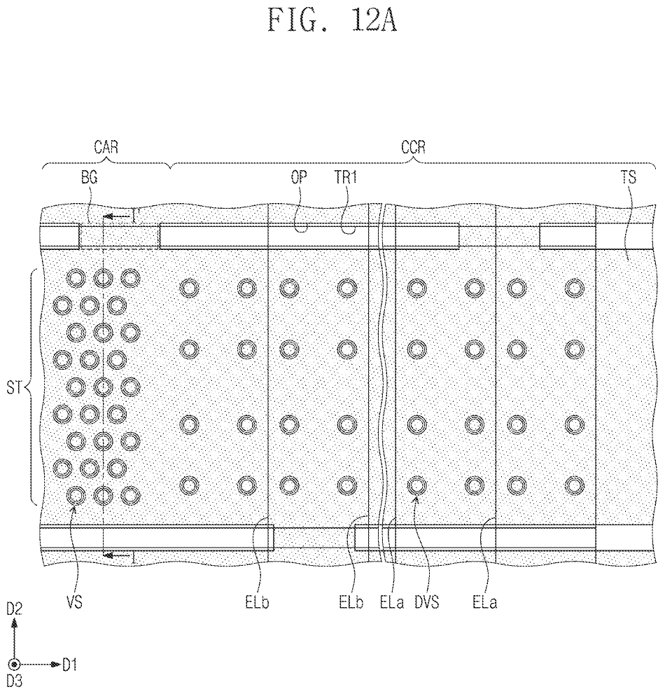

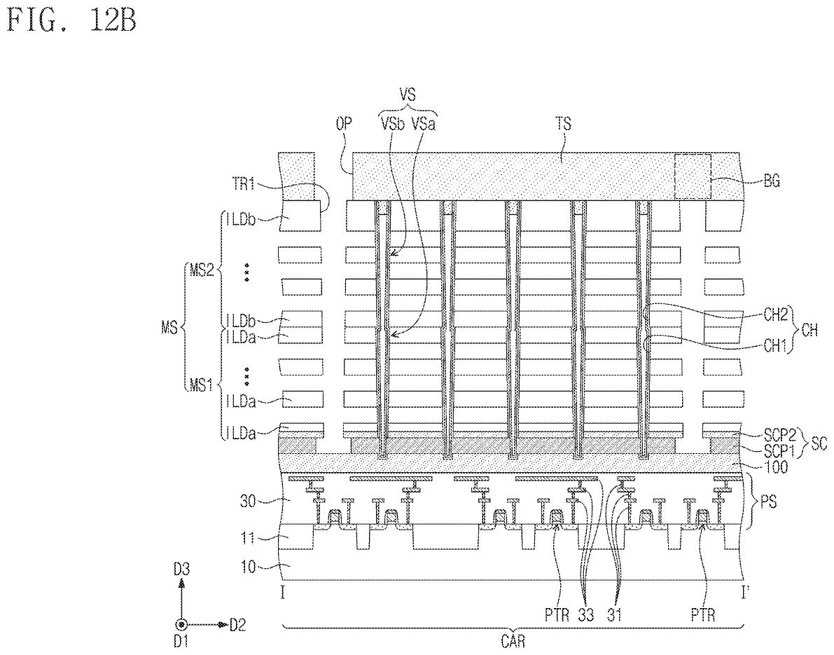

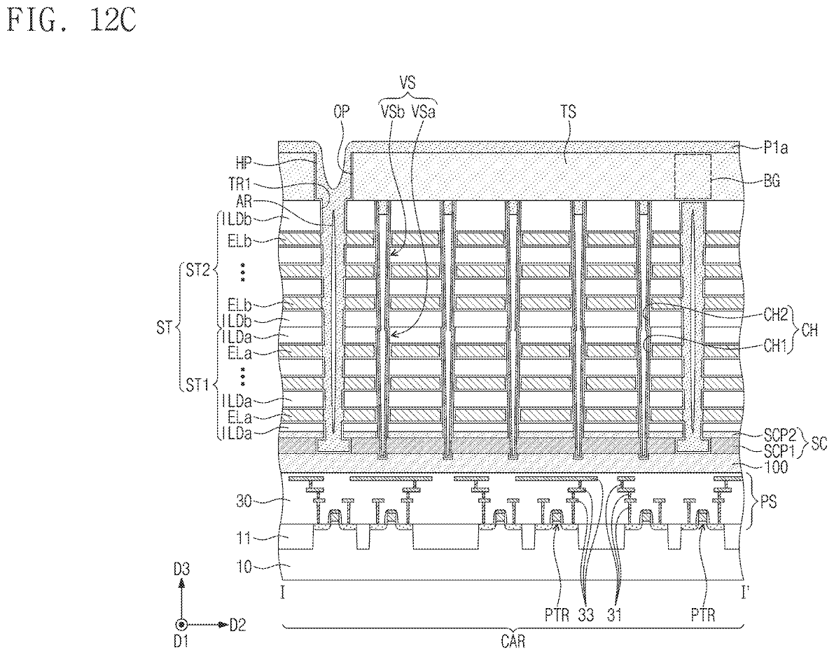

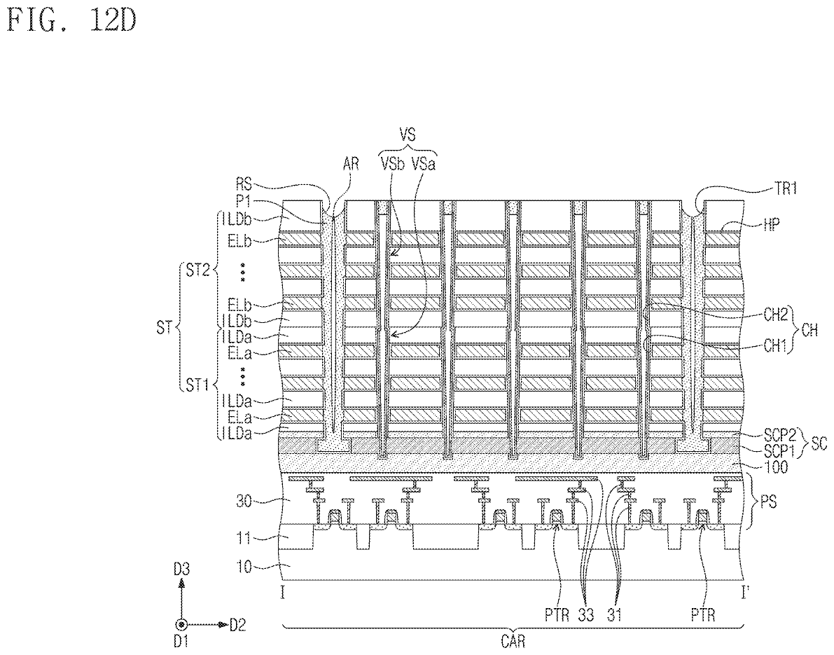

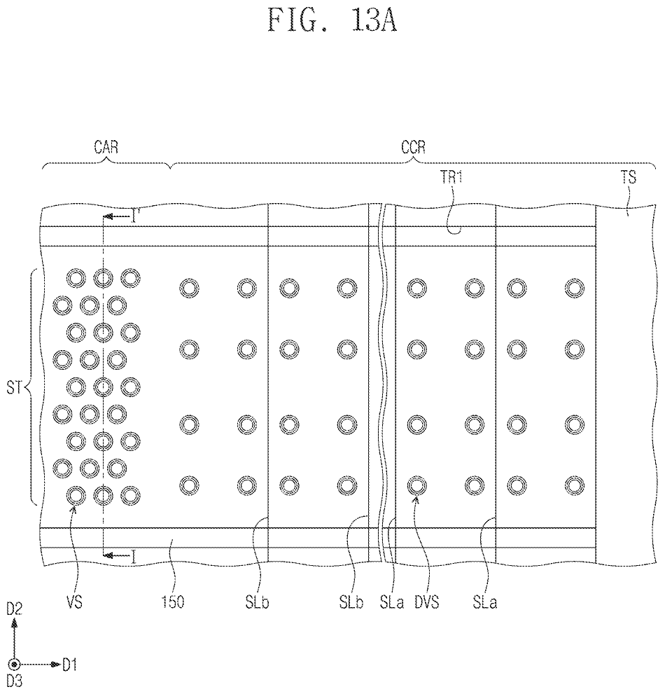

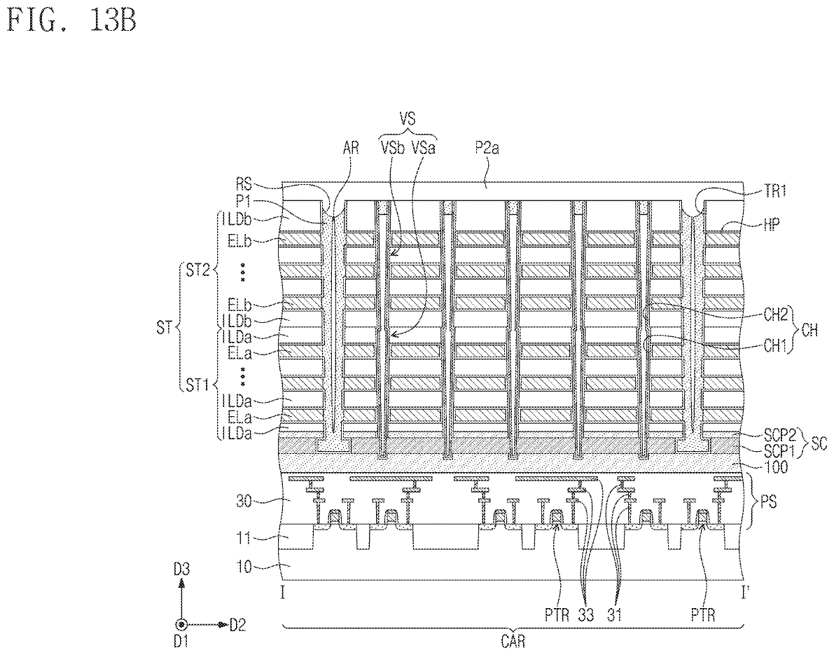

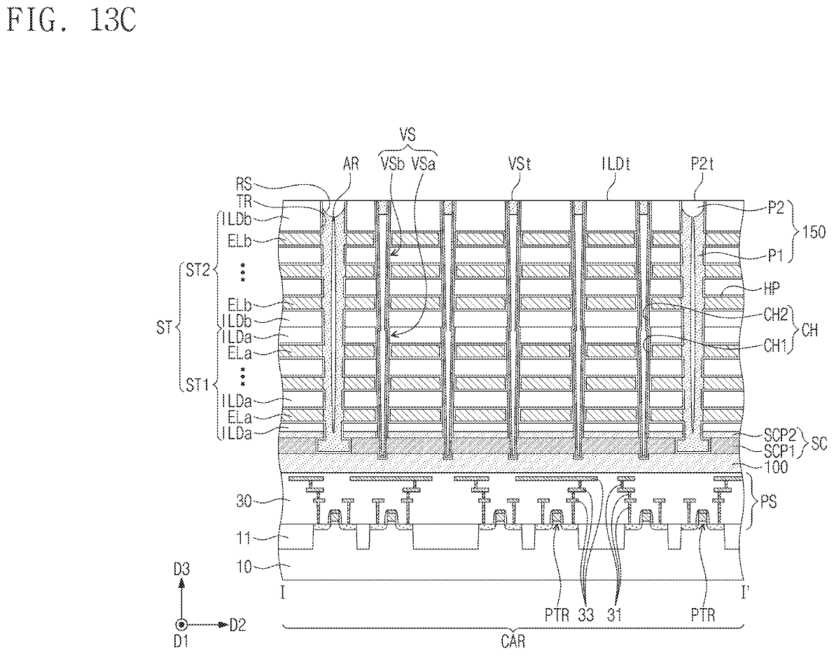

FIGS. 10A to 13C illustrate plan and cross-sectional views showing an example of a method of fabricating a three-dimensional semiconductor memory device. FIGS. 10A, 11A, 12A, and 13A illustrate plan views showing a three-dimensional semiconductor memory device. FIG. 10B illustrates a cross-sectional view taken along line I-I′ of FIG. 10A. FIG. 11B illustrates a cross-sectional view taken along line I-I′ of FIG. 11A. FIGS. 12B, 12C, and 12D illustrate cross-sectional views taken along line I-I′ of FIG. 12A. FIGS. 13B and 13C illustrate cross-sectional views taken along line I-I′ of FIG. 13A.

Referring to FIGS. 10A and 10B, a first substrate 10 may be provided that includes a cell array region CAR and a contact region CCR. A device isolation layer 11 defining an active section may be formed in the first substrate 10. The device isolation layer 11 may be formed by forming a trench on an upper portion of the first substrate 10 and filling the trench with silicon oxide.

Peripheral circuit transistors PTR may be formed on the active section defined by the device isolation layer 11. Peripheral contact plugs 31 and peripheral circuit lines 33 may be formed and are connected to the peripheral circuit transistors PTR. A first dielectric layer 30 may be formed to cover the peripheral circuit transistors PTR, the peripheral contact plugs 31, and the peripheral circuit lines 33.

A second substrate 100 may be formed on the first dielectric layer 30. The second substrate 100 may extend from the cell array region CAR toward the contact region CCR.

A lower sacrificial layer 117 and a semiconductor layer 121 may be formed on the second substrate 100. A mold structure MS may be formed on the semiconductor layer 121. The formation of the mold structure MS may include forming a first mold structure MS1 by alternately stacking first interlayer dielectric layers ILDa and first sacrificial layers SLa on the second substrate 100, and forming a second mold structure MS2 by alternately stacking second interlayer dielectric layers ILDb and second sacrificial layers SLb on the first mold structure MS1.

The first and second sacrificial layers SLa and SLb may be formed of a dielectric material different from that of the first and second interlayer dielectric layers ILDa and ILDb. The first and second sacrificial layers SLa and SLb may be formed of a material having an etch selectivity with respect to the first and second interlayer dielectric layers ILDa and ILDb. For example, the first and second sacrificial layers SLa and SLb may be formed of silicon nitride, and the first and second interlayer dielectric layers ILDa and ILDb may be formed of silicon oxide. The first and second sacrificial layers SLa and SLb may be formed to have substantially the same thickness. The first and second interlayer dielectric layers ILDa and ILDb may have thicknesses that are changed on a certain area.

A trimming process may be performed on the mold structure MS on the contact region CCR. The trimming process may include forming a mask pattern that partially covers a top surface of the mold structure MS on the cell array region CAR and the contact region CCR, using the mask pattern to pattern the mold structure MS, reducing an area of the mask pattern, and using the reduced mask pattern to pattern the mold structure MS. Reducing the area of the mask pattern and using the reduced mask pattern to pattern the mold structure MS may be performed alternately and repeatedly. The trimming process may cause the mold structure MS to have a stepwise structure on the contact region CCR.

Vertical channel holes CH may be formed to penetrate the mold structure MS, and first and second vertical channel structures VSa and VSb may be formed to fill the vertical channel holes CH. On the cell array region CAR, the vertical channel holes CH may penetrate the mold structure MS, the semiconductor layer 121, and the lower sacrificial layer 117. The vertical channel holes CH may penetrate at least a portion of the second substrate 100 and may each have a bottom surface at a level lower than that of a top surface of the second substrate 100.

The formation of the first and second vertical channel structures VSa and VSb may include forming a data storage pattern (see DSP of FIGS. 8A to 8C) that conformally covers an inner sidewall of each of the vertical channel holes CH, forming a vertical semiconductor pattern (see VSP of FIGS. 8A to 8C) that conformally covers a sidewall of the data storage pattern DSP, forming a buried dielectric pattern (see VI of FIGS. 8A to 8C) that fills at least a portion of a space surrounded by the vertical semiconductor pattern VSP, and forming a conductive pad (see PAD of FIGS. 8A to 8C) that fills a space surrounded by the vertical semiconductor pattern VSP and the buried dielectric pattern VI.

Referring to FIGS. 11A and 11B, a plurality of first trenches TR1 may be formed to penetrate the mold structure MS, the semiconductor layer 121, and the lower sacrificial layer 117. The first trenches TR1 may be formed by an anisotropic etching process. The first trenches TR1 may extend in the first direction D1 and may be spaced apart from each other in the second direction D2. The first trenches TR1 may outwardly expose a portion of the top surface of the second substrate 100. The first trenches TR1 may penetrate at least a portion of the second substrate 100. For example, the first trenches TR1 may each have a bottom surface located at a level lower than that of the top surface of the second substrate 100, but the present disclosure is not limited thereto.

A sacrificial pattern 150a may be formed to fill the first trenches TR1. The sacrificial pattern 150a may include a material having an etch selectivity with respect to the first and second interlayer dielectric layers ILDa and ILDb and the first and second sacrificial layers SLa and SLb. The sacrificial pattern 150a may include, for example, polycrystalline silicon.

Although not shown, before the formation of the sacrificial pattern 150a, spacers may be formed to cover sidewalls of the first trenches TR1 and to expose the bottom surfaces of the first trenches TR1.

Referring to FIGS. 12A and 12B, an upper support layer TS may be formed to cover the mold structure MS and the vertical channel structures VS. The upper support layer TS may contact an uppermost one of the first and second interlayer dielectric layers ILDa and ILDb. The upper support layer TS may be formed by chemical vapor deposition (CVD) and/or atomic layer deposition (ALD). For example, the upper support layer TS may include at least one selected from silicon oxide, silicon oxynitride, and silicon carbonitride.

Openings OP penetrating through the upper support layer TS in the third direction D3 may be formed. The openings OP may be formed by an anisotropic etching process such as plasma etching or reactive ion etching. The openings OP may extend in the first direction D1 and may be spaced apart from each other in the first and second directions D1 and D2. The openings OP may overlap vertically (e.g., in the third direction D3) with the first trenches TR1. The upper support layer TS may include bridges BG between the openings OP that are adjacent to each other in the first direction D1.

The sacrificial pattern 150a may be removed through the openings OP. Therefore, the first trenches TR1 may be outwardly exposed again. The bridges BG of the upper support layer TS may support the mold structure MS on the first trenches TR1 that become empty spaces due to removal of the sacrificial pattern 150a. The selective removal of the sacrificial pattern 150a may be achieved by performing an etching process in which a hydrofluoric acid is used as an etchant.

A first source conductive pattern SCP1 may replace the lower sacrificial layer 117 whose lateral surface is exposed by the first trenches TR1. For example, the lower sacrificial layer 117 may be selectively removed by the first trenches TR1. The removal of the lower sacrificial layer 117 may outwardly expose lower portions of the vertical channel structures VS. As shown in FIG. 9, a portion of the data storage pattern DSP of the vertical channel structures VS may also be removed. The first source conductive pattern SCP1 may be formed in a space where the lower sacrificial layer 117 is removed. The semiconductor layer 121 may be called a second source conductive pattern SCP2. Therefore, a source structure SC including the first and second source conductive patterns SCP1 and SCP2 may also be removed.

The first and second sacrificial layers SLa and SLb exposed by the first trenches TR1 may be selectively removed. The removal of the first and second sacrificial layers SLa and SLb may be achieved by performing a wet etching process with an etching solution having an etch selectivity.

The selective removal of the first and second sacrificial layers SLa and SLb may introduce structural weakness to the first and second mold structures MS1 and MS2 that are spaced apart from each other across the first trenches TR1. Thus, the first and second mold structures MS1 and MS2 may collapse or tilt. As the bridges BG of the upper support layer TS support the first and second mold structures MS1 and MS2 on the first trenches TR1, the first and second mold structures MS1 and MS2 may be supported during the formation of first and second gate electrodes ELa and ELb which will be discussed below.

Referring to FIGS. 12A and 12C, an interfacial dielectric layer HP may be formed to cover surfaces of the first and second interlayer dielectric layers ILDa and ILDb. The interfacial dielectric layer HP may extend toward spaces where the first and second sacrificial layers SLa and SLb are removed and may thus cover portions of lateral surfaces of the first and second vertical channel structures VSa and VSb.

First and second gate electrodes ELa and ELb may be formed to fill the spaces where the first and second sacrificial layers SLa and SLb are removed. In conclusion, a stack structure ST may be formed to include the first and second gate electrodes ELa and ELb and the first and second interlayer dielectric layers ILDa and ILDb.

A first preliminary dielectric pattern P1a may be formed in the first trenches TR1. The first preliminary dielectric pattern P1a may cover a top surface of the upper support layer TS, while filling the first trenches TR1. The first preliminary dielectric pattern P1a may cover a lateral surface of the upper support layer TS exposed by the openings OP.

The first preliminary dielectric pattern P1a may be formed by, for example, chemical vapor deposition (CVD) and/or atomic layer deposition (ALD). A seam AR may be formed in the first preliminary dielectric pattern P1a may be formed due to high aspect ratios of the first trenches TR1. The first preliminary dielectric pattern P1a may include, for example, silicon nitride.

Referring to FIGS. 12A and 12D, a first planarization process may be performed on the first preliminary dielectric pattern P1a and the upper support layer TS. The first planarization process may remove the upper support layer TS and a portion of the first preliminary dielectric pattern P1a. The first planarization process may outwardly expose a top surface of the uppermost one of the interlayer dielectric layers ILDa and ILDb and top surfaces of the vertical channel structures VS. Thus, the first preliminary dielectric pattern P1a may have a top surface located at a level substantially the same as that of the top surface of the uppermost one of the interlayer dielectric layers ILDa and ILDb and that of the top surfaces of the vertical channel structures VS. In this case, the seam AR may not be outwardly exposed. The first planarization process may include, for example, a chemical mechanical polishing (CMP) process or an etch-back process.

A portion of the first preliminary dielectric pattern P1a may further be removed. Therefore, a first portion P1 may be formed from the first preliminary dielectric pattern P1a. An etching process may be performed to remove a portion of the first preliminary dielectric pattern P1a. The etching process may be a wet etching process, for example, using a high selective nitride etchant (HSN). The HSN may include no fluorine and may selectively remove only silicon nitride. Therefore, the uppermost one of the interlayer dielectric layers ILDa and ILDb may remain in place. A portion of the first preliminary dielectric pattern P1a may be removed to form a recess RS. In this case, the recess RS may outwardly expose the seam AR.

As no fluorine is used in the etching process where a portion of the first preliminary dielectric pattern P1a is removed to form the first portion P1, the first and second gate electrodes ELa and ELb may be prevented from degradation caused by fluorine. In conclusion, a three-dimensional semiconductor memory device may improve in reliability and electrical properties.

Referring to FIGS. 13A and 13B, a second preliminary dielectric pattern P2a may be formed to fill the recess RS. The second preliminary dielectric pattern P2a may cover the top surface of the uppermost one of the interlayer dielectric layers ILDa and ILDb and the top surface of the vertical channel structures VS. As the second preliminary dielectric pattern P2a fills the recess RS, the second preliminary dielectric pattern P2a may contact the first portion P1 and the seam AR. Therefore, the seam AR may be isolated from external contact.

The second preliminary dielectric pattern P2a may be formed by chemical vapor deposition (CVD) and/or atomic layer deposition (ALD). The second preliminary dielectric pattern P2a may include a dielectric material, such as silicon oxide, different from that of the first portion P1.

Referring to FIGS. 13A and 13C, a second planarization process may be performed on the second preliminary dielectric pattern P2a. The second planarization process may remove a portion of the second preliminary dielectric pattern P2a. A portion of the second preliminary dielectric pattern P2a may be removed to form a second portion P2 from the second preliminary dielectric pattern P2a. The second planarization process may include, for example, a chemical mechanical polishing (CMP) process or an etch-back process.

The second planarization process may outwardly expose a top surface ILDt of the uppermost one of the interlayer dielectric layers ILDa and ILDb and top surfaces VSt of the vertical channel structures VS. Thus, the second preliminary dielectric pattern P2a may have a top surface P2t located at a level substantially the same as that of the top surface ILDt of the uppermost one of the interlayer dielectric layers ILDa and ILDb and that of the top surfaces VSt of the vertical channel structures VS.

As the second portion P2 includes silicon oxide, an ordinary fabrication method may be employed to form a selection mold structure SSLM, which will be discussed below. There may be no change in subsequent process after the formation of the second portion P2. As a result, it may be possible to easily fabricate a three-dimensional semiconductor memory device.

Referring back to FIGS. 5 to 7, the stack structure ST may be disposed thereon the selection mold structure SSLM, which includes first capping dielectric layer 210, a second capping dielectric layer 220, a third capping dielectric layer 230, a selection semiconductor layer 240, and a mold dielectric layer 250, which are sequentially formed.

A separation dielectric pattern 241 and upper separation structures 160 may be formed to penetrate the selection mold structure SSLM. From a plan view, the separation dielectric pattern 241 and the upper separation structures 160 may extend in the first direction D1 and may be spaced apart from each other in the second direction D2. The separation dielectric pattern 241 may be positioned between the upper separation structures 160. The separation dielectric pattern 241 and the upper separation structures 160 may include the same dielectric material. The separation dielectric pattern 241 and the upper separation structures 160 may be formed simultaneously with each other, but the present disclosure is not limited thereto.

On the cell array region CAR, upper vertical channel structures UVS may be formed to penetrate the selection mold structure SSLM. The formation of the upper vertical channel structures UVS may be substantially the same as that of the vertical channel structures VS discussed above.

On the contact region CCR, contact plugs CP may be formed to penetrate the selection mold structure SSLM. The contact plug CP may be electrically connected to the cell contact plug CCP or the peripheral contact plug TCP. A third dielectric layer 260 may be formed to cover the mold dielectric layer 250, the upper vertical channel structure UVS, the separation dielectric pattern 241, the upper separation structures 160, and the contact plugs CP.

On the cell array region CAR, bit-line contact plugs BLCP may be formed to penetrate the third dielectric layer 260 to connect with the upper vertical channel structures UVS. On the contact region CCR, conductive line contact plugs CLCP may be formed to penetrate the third dielectric layer 260 to come into connection with the contact plugs CP. The third dielectric layer 260 may be provided thereon with bit lines BL formed to come into connection with the bit-line contact plugs BLCP and with first conductive lines CL1 and second conductive lines CL2 that are formed to come into connection with the conductive line contact plugs CLCP.

In a three-dimensional semiconductor memory device, stack structures may be provided therebetween with a separation structure including a first portion and a second portion. The second portion may be positioned on the first portion and may include a dielectric material different from that of the first portion.

For example, as the first portion includes silicon nitride, no fluorine may be used to remove a portion of the first portion. Therefore, gate electrodes of stack structures may be prevented from degradation caused by fluorine. In addition, as the second portion includes silicon oxide, there may be no change in subsequent process after the formation of the separation structure. In conclusion, the three-dimensional semiconductor memory device may improve in reliability and electrical properties.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

Although the present disclosure has been described in connection with the embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A three-dimensional semiconductor memory device, comprising:
a plurality of stack structures comprising a plurality of interlayer dielectric layers and a plurality of gate electrodes that are alternately stacked on a substrate;
a plurality of vertical channel structures penetrating the plurality of stack structures; and
a separation structure extending in a first direction across between adjacent stack structures of the plurality of stack structures,
wherein the separation structure includes:
a first portion extending in a vertical direction from the substrate and a second portion on the first portion, the second portion including a material different from a material of the first portion, and
wherein a level of a top surface of the second portion is a same as a level of top surfaces of the plurality of vertical channel structures.

2. The three-dimensional semiconductor memory device of claim 1, wherein the separation structure is spaced apart from the plurality of vertical channel structures in a second direction, the second direction intersecting the first direction.

3. The three-dimensional semiconductor memory device of claim 2, wherein the first portion is in contact with the gate electrodes adjacent to each other in the second direction.

4. The three-dimensional semiconductor memory device of claim 1, wherein the first portion has a seam therein, and wherein the seam is in contact with the second portion.

5. The three-dimensional semiconductor memory device of claim 1, wherein the first portion includes silicon nitride, and wherein the second portion includes silicon oxide.

6. The three-dimensional semiconductor memory device of claim 1, wherein the second portion has a shape that is convex toward the substrate.

7. The three-dimensional semiconductor memory device of claim 1, wherein a bottom surface of the second portion is parallel to the top surface of the second portion.

8. The three-dimensional semiconductor memory device of claim 1, further comprising an interfacial dielectric layer between the plurality of vertical channel structures and the gate electrodes,
wherein the interfacial dielectric layer extends between the interlayer dielectric layers and the separation structure.

9. The three-dimensional semiconductor memory device of claim 1, wherein the separation structure has a largest width at a level lower than the top surface of the second portion.

10. The three-dimensional semiconductor memory device of claim 1, wherein the second portion is in an uppermost one of the interlayer dielectric layers.

11. The three-dimensional semiconductor memory device of claim 1, further comprising:
a selection mold structure on the plurality of stack structures, the selection mold structure including a selection semiconductor layer; and
an upper separation structure penetrating the selection mold structure and contacting the second portion.

12. The three-dimensional semiconductor memory device of claim 11, wherein the first portion is spaced apart in the vertical direction from the selection mold structure.

13. A three-dimensional semiconductor memory device, comprising:
a substrate comprising a cell array region and a contact region adjacent to the cell array region in a first direction;
a peripheral circuit structure on the substrate, the peripheral circuit structure including a plurality of peripheral circuit transistors;
a source structure on the peripheral circuit structure;
a plurality of stack structures comprising a plurality of interlayer dielectric layers and a plurality of gate electrodes that are alternately stacked on the source structure;
a plurality of vertical channel structures that penetrate the plurality of stack structures and are connected to the source structure;
a separation structure extending in the first direction across between adjacent stack structures of the plurality of stack structures;
a selection mold structure on the plurality of stack structures, the selection mold structure comprising a selection semiconductor layer;
an upper separation structure penetrating the selection mold structure and contacting the separation structure;
a plurality of upper vertical channel structures penetrating the selection mold structure and correspondingly connected to the plurality of vertical channel structures; and
a separation dielectric pattern in the selection mold structure, the separation dielectric pattern penetrating the selection semiconductor layer,
wherein the separation structure includes a first portion on the source structure; and
a second portion between the first portion and the selection mold structure, and
wherein a top surface of the second portion is at a level the same as a level of top surfaces of the plurality of vertical channel structures.

14. The three-dimensional semiconductor memory device of claim 13, wherein the first portion and the second portion include different materials from each other.

15. The three-dimensional semiconductor memory device of claim 13, wherein the second portion has a shape that is convex toward the source structure.

16. The three-dimensional semiconductor memory device of claim 13, further comprising:
a planarized dielectric layer that covers the plurality of stack structures; and
a plurality of cell contact plugs on the contact region, the cell contact plugs penetrating the planarized dielectric layer and correspondingly contacting the gate electrodes.

17. The three-dimensional semiconductor memory device of claim 16, wherein the cell contact plugs are electrically connected to the peripheral circuit transistors of the peripheral circuit structure.

18. An electronic system, comprising:
a three-dimensional semiconductor memory device comprising a substrate, a plurality of stack structures including a plurality of interlayer dielectric layers and a plurality of gate electrodes that are alternately stacked on the substrate, a plurality of vertical channel structures penetrating the plurality of stack structures, a separation structure between adjacent stack structures of the plurality of the stack structures, and an input/output pad on the plurality of stack structures; and
a controller that has electrical connection through the input/output pad with the three-dimensional semiconductor memory device and controls the three-dimensional semiconductor memory device,
wherein the separation structure includes a first portion that extends in a vertical direction from the substrate, and
a second portion on the first portion, the second portion including a material different from a material of the first portion,
wherein a level of a top surface of the separation structure is the same as a level of top surfaces of the plurality of stack structures.

19. The electronic system of claim 18, wherein the first portion includes silicon nitride, and wherein the second portion includes silicon oxide and has a shape that is convex toward the substrate.

20. The electronic system of claim 18, further comprising a selection mold structure on the plurality of stack structures, the selection mold structure including a selection semiconductor layer.
